(19) United States
(12) Patent Application Publication
(10) Pub. No.: US 2025/0385114 A1
(43) Pub. Date: Dec. 18, 2025

(54) SUBSTRATE TRANSFER APPARATUS

(71) Applicant: VM Inc., Icheon-si (KR)

(72) Inventors: Sang Woo Lee, Suwon-si (KR); Woo Hyung Choi, Seongnam-si (KR)

(21) Appl. No.: 18/894,966

(22) Filed: Sep. 24, 2024

(30) Foreign Application Priority Data
Jun. 14, 2024 (KR) 10-2024-0077364

(51) Int. Cl. H01L 21/677; B65G 54/02

(52) U.S. Cl. CPC H01L 21/67709; B65G 54/02

(57) ABSTRACT

Disclosed is a substrate transfer apparatus including a moving plate including a magnetic levitation rail, a plurality of processing chambers disposed adjacent to the moving plate, and that process a substrate, and a plurality of shuttles that are moved on the moving plate by using the magnetic levitation rail, and transport the substrate from any one to another one of the plurality of processing chambers.

### STATEMENT REGARDING GOVERNMENT SPONSORED RESEARCH OR DEVELOPMENT

The present disclosure was developed in the task of a project to develop next-generation 300 mm high aspect ratio process oxide film dry etching equipment (Project identification number: 1415182778, Project number: P0021943, Ministry name: Ministry of Trade, Industry and Energy, Project management organization name: Korea Institute for Advancement of Technology, Research project name: World Class Plus Project Support, Project implementation organization name: APTC Co., Ltd. (VM Inc.), Research period Jun. 1, 2022˜Dec. 31, 2025)

Meanwhile, in all the aspects of the inventive concept, there is no property interest in the government of the Republic of Korea.

### CROSS-REFERENCE TO RELATED APPLICATIONS

This application claims priority under 35 U.S.C. § 119 to Korean Patent Application No. 10-2024-0077364 filed on Jun. 14, 2024, in the Korean Intellectual Property Office, the disclosures of which are incorporated by reference herein in their entireties.

### BACKGROUND

Embodiments of the present disclosure described herein relate to a substrate transfer apparatus, and more particularly, to a substrate transfer apparatus that efficiently transfers a substrate by using a plurality of shuttles.

A throughput in equipment used in semiconductor or display processes refers to an amount of wafers or substrates processed per unit time in a single process. The throughput may be determined based on a processing time of a processing chamber, an intake/exhaust speed of a vacuum robot, a cooling/heating time of wafers, an environment for a process before proceeding with the process, and the like. However, there are limits in maximizing the throughput of equipment based on the factors alone.

### SUMMARY

Embodiments of the present disclosure provide a substrate transfer apparatus that efficiently transfers a substrate by using a plurality of shuttles.

According to an aspect of the present disclosure, a substrate transfer apparatus includes a moving plate including a magnetic levitation rail, a plurality of processing chambers disposed adjacent to the moving plate, and that process a substrate, and a plurality of shuttles that are moved on the moving plate by using the magnetic levitation rail, and transport the substrate from any one to another one of the plurality of processing chambers.

Here, the plurality of processing chambers may include a first processing chamber group being adjacent to one end of the moving plate and a second processing chamber group being adjacent to an opposite end of the moving plate, and the magnetic levitation rail may include a first rail area being adjacent to the first processing chamber group and a second rail area being adjacent to the second processing chamber group.

Here, the magnetic levitation rail may further include a third rail area connecting the first rail area and the second rail area.

Here, the plurality of shuttles may include a first shuttle and a second shuttle, and, not to obstruct a first path being a movement path of the first path, which includes an area of the magnetic levitation rail, the second shuttle may stop in another area of the magnetic levitation rail.

Here, the plurality of shuttles may include a first shuttle and a second shuttle, and, when a path of the first shuttle and a path of the second shuttle overlap each other in a first area, the second shuttle may stop in a second area of a third rail, which is adjacent to the first area.

Here, the second shuttle that stopped in the second area may be moved from the second area to the first area after the first shuttle passes through the first area.

Here, the substrate transfer apparatus may further include a load lock chamber disposed adjacent to the moving plate, the plurality of shuttles may include a first shuttle, and the first shuttle may stop in a predetermined area of the magnetic levitation rail while the substrate is transferred between the first shuttle and the load lock chamber.

Here, the moving plate may include an arm that transports the substrate in the plurality of processing chambers or the plurality of shuttles.

Here, the arm may be disposed between the first rail area and the second rail area.

Here, the magnetic levitation rail may include a third rail area connecting the first rail area and the second rail area, and the arm may be surrounded by the first rail area, the second rail area, and the third rail area.

### BRIEF DESCRIPTION OF DRAWINGS

The above and other objects and features of the present disclosure will become apparent by describing in detail embodiments thereof with reference to the accompanying drawings.

FIGS. 1 and 2 are plan views of a substrate transfer apparatus including a plurality of arms and a plurality of shuttles according to an embodiment of the present disclosure.

FIG. 3 is a plan view of each of substrate transfer apparatuses including different types of magnetic levitation rails according to an embodiment of the present disclosure.

FIG. 4 is a plan view of a substrate transfer apparatus, in which a stopping area of a shuttle is changed, according to an embodiment of the present disclosure.

### DETAILED DESCRIPTION OF EXEMPLARY EMBODIMENTS

Hereinafter, details for implementation of the present disclosure will be described in detail with reference to the attached drawings. However, in the following description, a detailed description of widely known functions or configurations will be omitted when there is a risk of unnecessarily obscuring the gist of the present disclosure.

In the accompanying drawings, identical or corresponding components are given the same reference numerals. Furthermore, in a description of the following embodiments, a repeated description of identical or corresponding components may be omitted. However, even if a description of components is omitted, it is not intended that such components are not included in any embodiment.

Advantages and features of the disclosed embodiments and methods for achieving them will become clear with reference to the embodiments described below along with the accompanying drawings. However, the present disclosure is not limited to the embodiments disclosed below and may be implemented in various different forms, and the embodiments only ensure that the present disclosure is complete and that the present disclosure discloses the scope of the invention to those skilled in the art.

Terms used in the specification will be briefly described, and the disclosed embodiment will be described in detail. The terms used in the specification are currently widely used general terms that are selected as much as possible while considering their function in the present disclosure, but this may vary depending on the intention or precedent of engineers working in the related field, the emergence of new technologies, and the like. In addition, in certain cases, there are terms arbitrarily selected by the applicant, and in this case, the meaning will be described in detail in the description of the relevant invention. Therefore, the terms used in the present disclosure should be defined based on the meaning of the term and the overall content of the present disclosure, rather than simply the name of the term.

In the specification, singular expressions include plural expressions, unless the context clearly specifies singular expressions. Additionally, plural expressions include singular expressions, unless the context clearly specifies plural expressions. When it is said that a part ‘includes’ a certain element throughout the specification, this means that it does not exclude other elements, but may further include other elements, unless specifically stated to the contrary.

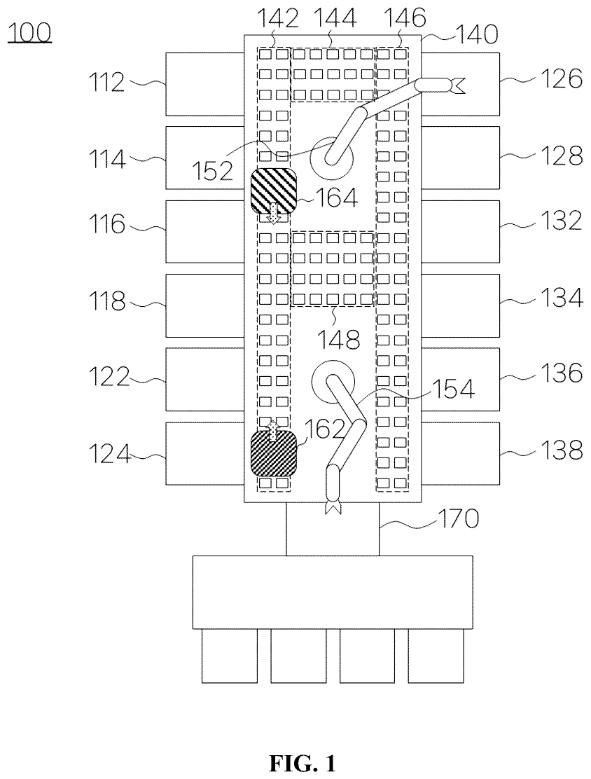

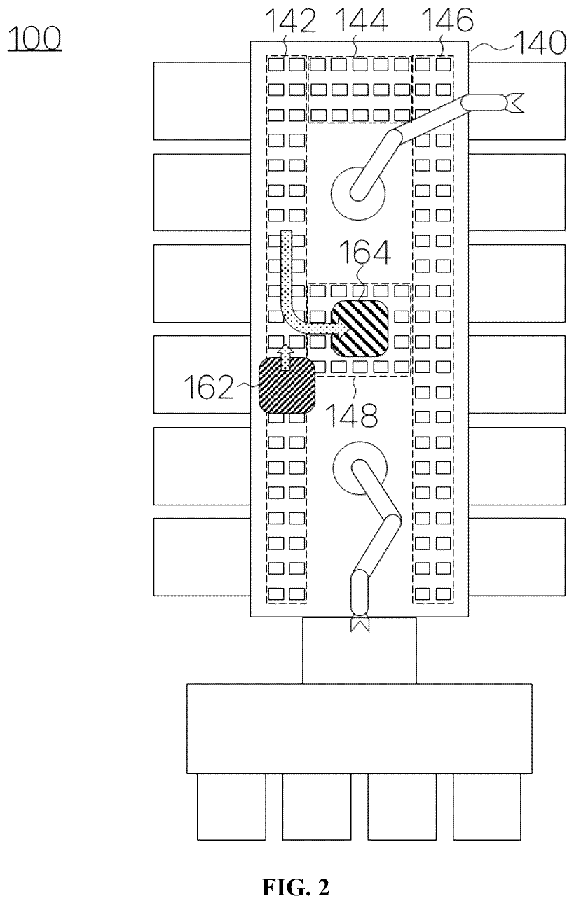

FIGS. 1 and 2 are plan views of a substrate transfer apparatus 100 including a plurality of arms 152 and 154 and a plurality of shuttles 162 and 164 according to an embodiment of the present disclosure. As illustrated, the substrate transfer apparatus 100 may include at least one of a plurality of processing chambers 112 to 138, a moving plate 140, a magnetic levitation rail(s) 142 to 148, a plurality of arms 152 and 154, and a plurality of shuttles 162 and 164. Furthermore, the substrate transfer apparatus may further include a load lock chamber 170 that is disposed adjacent to the moving plate 140.

The first shuttle 162 and/or the second shuttle 164 may be moved along the magnetic levitation rail(s) 142 to 148, respectively, to transfer the substrate (hereinafter, the first shuttle 162 will be mainly described). In detail, the first shuttle 162 may acquire a substrate from any one of the plurality of processing chambers 112 to 138 and transfer the acquired substrate along the magnetic levitation rails 142 to 146. Thereafter, the substrate may be delivered to the load lock chamber 170 by at least one of the plurality of arms 152 and 154.

The plurality of processing chambers may include a first processing chamber group that is adjacent to one end of the moving plate 140 and a second processing chamber group that is adjacent to an opposite end of the moving plate 140. In detail, with reference to FIG. 1, the first processing chamber group may include processing chambers 112, 114, 116, 118, 122, and 124 that are disposed on a left side of the moving plate 140. Furthermore, the second processing chamber group may include processing chambers 126, 128, 132, 134, 136, and 138 that are disposed on a right side of the moving plate 140.

The magnetic levitation rails 142 to 148 may include a plurality of areas. In detail, the magnetic levitation rail 142 to 148 may include a first rail area 142 that is disposed along a longitudinal direction at one periphery of one surface of the moving plate 140 and/or a second rail area 146 that is disposed along the longitudinal direction on an opposite periphery of the one surface of the moving plate 140.

The magnetic levitation rail may include a first rail area 142 that is adjacent to the first processing chamber group and a second rail area 146 that is adjacent to the second processing chamber group. The first rail area 142 may be disposed on the moving plate 140 closer to the first processing chamber group than to the second processing chamber group. Furthermore, the second rail area 146 may be disposed on the moving plate 140 closer to the second processing chamber group than to the first processing chamber group.

The magnetic levitation rail 142 to 148 may include a third rail area 144 and/or a fourth rail area 148 that is configured to connect the first rail area 142 and the second rail area 146. In this case, the third rail area 144 and/or the fourth rail area 148 may be disposed along a transverse direction of the moving plate 140 as illustrated in FIG. 1.

Meanwhile, the magnetic levitation rails 142 to 148 may include an area for stopping any one shuttle so that the plurality of shuttles 162 and 164 do not collide with each other while the plurality of shuttles 162 and 164 are moved. In this way, the area for stopping may be included in some specific areas of the magnetic levitation rail 142 to 148.

Alternatively, the area for stopping may be selected as a partial area of the magnetic levitation rails 142 to 148 based on movement directions and/or locations of the plurality of shuttles 162 and 164. Additionally or alternatively, the magnetic levitation rails 142 to 148 may include a third rail area 144 and/or a fourth rail area 148 for moving one of the plurality of shuttles 162 and 164 from one periphery (that is, the first rail area 142) of the moving plate 140 to an opposite periphery (that is, the second rail area 144) of the moving plate 140.

The plurality of shuttles 162 and 164 may include a first shuttle 162 and/or a second shuttle 164. FIG. 1 illustrates that the plurality of shuttles 162 and 164 include two shuttles, but the present disclosure is not limited thereto. For example, the plurality of shuttles 162 and 164 may include three or more shuttles.

Each of the plurality of shuttles 162 and 164 may accommodate one or more substrates. For example, an arbitrary one of the plurality of shuttles 162 and 164 may transfer a target substrate that is to be processed in any one of the plurality of processing chambers 112 to 138 to the corresponding any one processing chamber while carrying it. As another example, an arbitrary shuttle may transfer a substrate processed in any one processing chamber to the load lock chamber 170 while carrying it.

For a path including one area of the magnetic levitation rails 142 to 148 to be provided to the first shuttle 162, the second shuttle 164 may stop in another predetermined area of the magnetic levitation rails 142 to 148. In this case, one of the plurality of shuttles 162 and 164, which stops in the other area, may be determined as a shuttle that is located relatively close to the other area.

The second shuttle 164 may stop in some areas of the magnetic levitation rail not to interfere with the movement path of the first shuttle 162. In detail, not to interfere with the first path of the first shuttle 162 including one area of the magnetic levitation rail, the second shuttle 164 may stop in another area of the magnetic levitation rail.

Alternatively, when the path of the first shuttle 162 and the path of the second shuttle 164 overlap in the first area (a specific area of the magnetic levitation rail), the second shuttle 164 may stop in the second area of the third rail, which is adjacent to the first area. The second shuttle 164 that stopped in the second area may be moved from the second area to the first area after the first shuttle 162 passes through the first area.

In detail, referring to FIG. 1, the first shuttle 162 is being moved upward along the first rail area 142, and the second shuttle 164 is being moved downward along the first rail area 142. In this case, the second shuttle 164 located relatively close to the fourth rail area 148, which is set as another area, may be moved to the fourth rail area 148 and may stop as illustrated in FIG. 2. Accordingly, the first shuttle 162 may continue to be moved along the first rail area 142.

However, the area, in which the second shuttle 164 stops, is not limited to the fourth rail area 148. For example, when a path including another area has to be provided to the first shuttle 162, the second shuttle 164 may stop in another area.

Meanwhile, FIGS. 1 and 2 illustrate an example, in which the plurality of shuttles 162 and 164 are moved along the same rail area, but the present disclosure is not limited thereto. For example, the first shuttle 162 is being moved from the first rail area 142 to the second rail area 146 via the third rail area 144, and the second shuttle 164 is being moved from the second rail area 146 to the first rail area 142 via the third rail area 144.

In this case, the first shuttle 162 located relatively close to the fourth rail area 148 may be moved to the second rail area 146 via the fourth rail area 148. Accordingly, the second shuttle 164 may be moved to the first rail area 142 via the third rail area 144. That is, the movement direction and/or the stopping position of the plurality of shuttles 162 and 164 may be controlled not to collide with each other.

In this case, the movement direction and/or the stopping position of each of the plurality of shuttles 162 and 164 may be determined so that a total movement direction of the plurality of shuttles 162 and 164 is minimized. With the configuration, the substrate transfer apparatus 100 may improve a throughput and reduce energy consumption by providing an efficient movement line to the plurality of shuttles 162 and 164.

The moving plate 140 of the substrate transfer apparatus 100 may include an arm 152 or 154 that is configured to transport a substrate in the plurality of processing chambers or the plurality of shuttles. Then, the arm may be disposed between the first rail area 142 and the second rail area 146. Furthermore, the arm may be disposed to be surrounded by the first rail area 142, the second rail area 146, and the third rail area 144 or 148, but the present disclosure is not limited thereto.

By disposing the arm 152 or 154 adjacent to the first rail area 142 to the third rail area 144 or 148, the arm 152 or 154 may easily, quickly, and efficiently transport a substrate to any rail area.

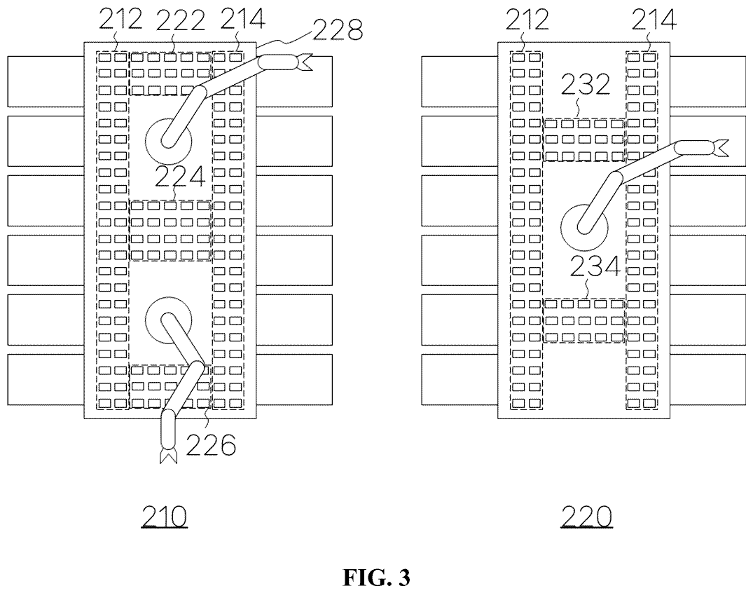

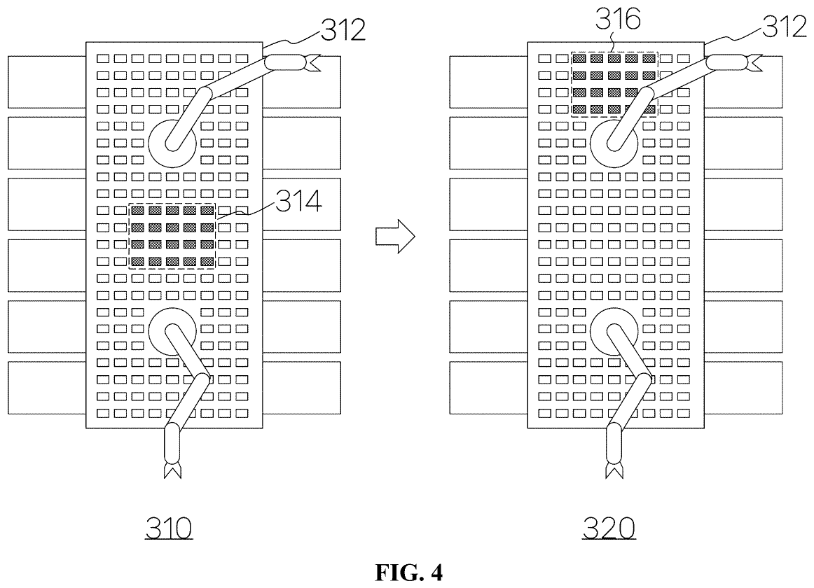

Hereinafter, in FIGS. 3 and 4, embodiments, in which the arm, the shuttle, and the magnetic levitation rail are configured in various shapes and/or numbers, will be described later. However, the disposition and/or the number of arms, the disposition and/or the number (of areas) of magnetic levitation rails, and the number of shuttles are not limited to the embodiments described later. That is, the number of the arms, the shuttles, and the magnetic levitation rails may each be one or more. Furthermore, the arm and magnetic levitation rail may be disposed on one surface of the moving plate differently from the position and/or the form illustrated in the present disclosure.

FIG. 3 is a plan view of each of substrate transfer apparatuses 210 and 220 including different types of magnetic levitation rails according to an embodiment of the present disclosure.

Referring to the first substrate transfer apparatus 210, the magnetic levitation rails 212 to 226 may include one or more rail areas 222 to 226 between the first rail area 212 disposed along the longitudinal direction on one periphery of the moving plate 228 and the second rail area 214 disposed along the longitudinal direction on an opposite periphery of the moving plate 228.

For example, the magnetic levitation rail 212 to 226 may include a third rail area 222 that is disposed along the transverse direction at an upper periphery between the first rail area 212 and the second rail area 214. As another example, the magnetic levitation rails 212 to 226 may include a fifth rail area 226 that is disposed along the transverse direction at a lower periphery between the first rail area 212 and the second rail area 214. As another example, the magnetic levitation rails 212 to 226 may include a fourth rail area 224 that is disposed along the transverse direction in an intermediate area (or between the plurality of arms) between the first rail area 212 and the second rail area 214.

Referring to the second substrate transfer apparatus 220, the magnetic levitation rails 212, 214, 232, and 234 may include one or more rail areas 232 to 234 between the first rail area 212 disposed along the longitudinal direction on one periphery of the moving plate 228 and the second rail area 214 disposed along the longitudinal direction on an opposite periphery of the moving plate 228.

For example, the magnetic levitation rails 212, 214, 232, and 234 may include a sixth rail area 232 that is disposed along the transverse direction in an intermediate area (or an upper side of the arm) between the first rail area 212 and the second rail area 214. As another example, the magnetic levitation rails 212, 214, 232, and 234 may include a seventh rail area 234 that is disposed along the transverse direction in another intermediate area (or a lower side of the arm) between the first rail area 212 and the second rail area 214.

FIG. 4 is a plan view of a substrate transfer apparatus 310, in which a stopping area of a shuttle is changed, according to an embodiment of the present disclosure. First, referring to the substrate transfer apparatus 310 on the left side, an example, in which an area, in which the shuttle(s) (e.g., the first shuttle 162 and/or the second shuttle 164) stops, is determined to be a first rail area 314 in the magnetic levitation rail disposed on a moving plate 312, is illustrated. However, the area, in which the shuttle(s) stops, may be changed, like the substrate transfer apparatus 320 on the right side, based on the location and/or the movement direction of each of the shuttle(s). As illustrated, the area, in which the shuttle(s) stops, may be changed from the first rail area 314 to the second rail area 316.

Meanwhile, as illustrated in FIG. 4, the magnetic levitation rail may be disposed on a front side of the moving plate 312. In detail, the magnetic levitation rail may be disposed on all areas of one surface of the moving plate 312, except for the area, in which the arm is disposed. Furthermore, it is illustrated in the present disclosure that all the areas, in which the shuttle(s) stops, are located between the rail area disposed on one periphery of the moving plate and the rail area disposed on an opposite periphery of the moving plate, but the present disclosure is not limited thereto. For example, the area, in which the shuttle(s) stops, may be determined as the rail area disposed on one periphery of the moving plate and/or the rail area disposed on the opposite periphery of the moving plate.

According to an embodiment of the present disclosure, a substrate transfer apparatus that efficiently transfers a substrate by using a plurality of shuttles may be provided.

Various modifications to the present disclosure will be readily apparent to those skilled in the art, and the general principles defined herein may be applied to the various modifications without departing from the spirit or scope of the present disclosure. Accordingly, the present disclosure is not intended to be limited to the examples set forth herein but is to be given the widest scope consistent with the principles and novel features disclosed herein.

Although example implementations may refer to utilizing aspects of the presently disclosed subject matter in the context of one or more standalone computer systems, the subject matter is not so limited, but may be implemented rather in conjunction with any computing environment, such as a network or distributed computing environment. Furthermore, aspects of the presently disclosed subject matter may be implemented in or across a plurality of processing chips or devices, and storage may be similarly effected across the plurality of devices. The devices may include PCs, network servers, and handheld devices.

Although the present disclosure has been described in relation to some embodiments in the specification, various modifications and changes may be made without departing from the scope of the present disclosure that may be understood by a person skilled in the art, to which the present disclosure pertains. Additionally, such modifications and changes should be considered to fall within the scope of the claims appended to the specification.

What is claimed is:

1. A substrate transfer apparatus comprising:
a moving plate including a magnetic levitation rail;
a plurality of processing chambers disposed adjacent to the moving plate, and configured to process a substrate; and
a plurality of shuttles configured to be moved on the moving plate by using the magnetic levitation rail, and transport the substrate from any one to another one of the plurality of processing chambers.

2. The substrate transfer apparatus of claim 1, wherein the plurality of processing chambers include a first processing chamber group being adjacent to one end of the moving plate and a second processing chamber group being adjacent to an opposite end of the moving plate, and
wherein the magnetic levitation rail includes a first rail area being adjacent to the first processing chamber group and a second rail area being adjacent to the second processing chamber group.

3. The substrate transfer apparatus of claim 2, wherein the magnetic levitation rail further includes a third rail area connecting the first rail area and the second rail area.

4. The substrate transfer apparatus of claim 1, wherein the plurality of shuttles include a first shuttle and a second shuttle, and
wherein, not to obstruct a first path being a movement path of the first shuttle, which includes an area of the magnetic levitation rail, the second shuttle stops in another area of the magnetic levitation rail.

5. The substrate transfer apparatus of claim 3, wherein the plurality of shuttles include a first shuttle and a second shuttle, and
when a path of the first shuttle and a path of the second shuttle overlap each other in a first area, the second shuttle stops in a second area of a third rail, which is adjacent to the first area.

6. The substrate transfer apparatus of claim 5, wherein the second shuttle that stopped in the second area is moved from the second area to the first area after the first shuttle passes through the first area.

7. The substrate transfer apparatus of claim 1, further comprising:
a load lock chamber disposed adjacent to the moving plate,
wherein the plurality of shuttles include a first shuttle, and
wherein the first shuttle stops in a predetermined area of the magnetic levitation rail while the substrate is transferred between the first shuttle and the load lock chamber.

8. The substrate transfer apparatus of claim 2, wherein the moving plate includes an arm configured to transport the substrate in the plurality of processing chambers or the plurality of shuttles.

9. The substrate transfer apparatus of claim 8, wherein the arm is disposed between the first rail area and the second rail area.

10. The substrate transfer apparatus of claim 8, wherein the magnetic levitation rail includes a third rail area connecting the first rail area and the second rail area, and
wherein the arm is surrounded by the first rail area, the second rail area, and the third rail area.
